(19) United States
(12) Patent Application Publication
(10) Pub. No.: US 2007/0017090 A1
(43) Pub. Date: Jan. 25, 2007

(54) Method of forming metal plate pattern and circuit board

(76) Inventors: Toyoaki Sakai, Nagano-shi (JP); Katsuya Fukase, Nagano-shi (JP)

Correspondence Address: CHADBOURNE & PARKE, L.L.P., 30 Rockefeller Plaza, New York, NY, 10112, US

(21) Appl. No.: 11/486,820

(22) Filed: Jul. 13, 2006

(30) Foreign Application Priority Data
Jul. 15, 2005 (JP) 2005-207034(PAT.)

(51) Int. Cl. H01B 13/00; H05K 3/00

(52) U.S. Cl. 29/829; 216/13

(57) ABSTRACT

A method of forming a high aspect ratio metal plate pattern and a circuit board by multi-stage etching with a metal mask is disclosed. A resist (12) is coated on one of two surfaces of a copper plate (10) and patterned to form a resist pattern. A tin plating layer (14) is formed using this resist pattern, and with this tin plating layer as a mask, the copper plate is selectively half etched. By coating, exposing and developing the positive resist (18), the side etched portion under the tin plating layer is protected by the positive resist. With the tin plating layer and the protective resist layer as a mask, the half etching is executed again. This process is repeated until the resist and the tin plating layer used as a mask are finally removed to produce a metal pattern (20).

### BACKGROUND OF THE INVENTION

1. Field of the Invention

This invention relates to a method of forming a metal plate pattern, such as a lead frame or a metal mask mesh or a wiring pattern on a printed circuit board, or, in particular, to a method of forming a high aspect ratio fine metal plate pattern, such a lead frame or a metal mask mesh, from a metal plate using semiadditive process pattern forming technique or a method of forming a fine wiring pattern on an insulating substrate to fabricate a printed circuit board.

2. Description of the Related Art

The subtractive process is an inexpensive, simple method of fabricating a printed circuit board and has been most widely used. On the other hand, in consideration of the recent trend toward a higher density and a smaller size of semiconductor devices and various electronic devices, the subtractive method is disadvantageous in some points when producing fine conductor patterns on a circuit board.

A method of forming a metal pattern has been proposed in which the etching process is provisionally suspended after being etched to a predetermined depth along the thickness of an etched layer and the side etched portion generated by the first etching session is covered by an anti-etching layer, after which the etching process is resumed.

A metal is etched in a plurality of stages to secure a high aspect ratio in any of the conventional techniques described below.

(1) The layer to be etched is coated with a dry film resist (DFR) as a mask, which is patterned by exposure and development, after which the layer to be etched is etched (by “half etching”). The term of “half etching” on “selective etching” in this specification means an etching by which the layer to be etched is not fully etched through the thickness thereof, but etched until a predetermined thickness thereof. The resulting side etched portion is protected by an anti-etching layer, and the etching process executed again thereby to produce a high-density pattern (Japanese Unexamined Patent Publication Nos. 1-188700 and 1-290289, for example). In this case, the use of a positive photosensitive resist (Japanese Unexamined Patent Publication No. 10-229153, for example) or an electrodeposit resist (Japanese Unexamined Patent Publication No. 2004-204251, for example) has been proposed as an anti-etching protective layer for the side etched portion.

These conventional techniques pose a problem, however, in that the light masking property of the DFR forming the anti-etching protective layer of the side etched portion is insufficient and therefore the positive resist under the DFR is melted and generates a gap with the DFR, resulting in the loss of the function as an anti-etching protective layer. Another problem is that the DFR is melted (expanded) and separated by the developer or the adhesion of the DFR is reduced and the DFR is separated by deformation under the liquid pressure of the developer during the development of the positive resist, resulting in the loss of the mask function.

(2) As described above, a method has been proposed in which the DFR is patterned by lamination as a mask on the etched layer, after which the light masking property of the DFR is improved by forming a toner layer as a masking layer on the DFR and the etching process is conducted in a plurality of stages (Japanese Unexamined Patent Publication No. 2005-026646, for example). Also in this case, the DFR is melted (expanded) and separated by the developer during the development of the positive resist or the deformation of the DFR under the liquid pressure of the developer reduces the adhesion of the DFR, which is thus separated.

(3) As in (2) above, a method has been proposed (in Japanese Unexamined Patent Publication No. 2005-026645, for example) in which the etching process is executed in a plurality of stages after forming a thin metal (silver) layer between the etched layer and the DFR to improve the light masking property of the DFR. This method also poses a problem that the DFR is melted (expanded) and separated by the developer during the development of the positive resist, and the liquid pressure of the developer deforms and damages the thin metal layer resulting in a loss of the mask function.

### SUMMARY OF THE INVENTION

Accordingly, it is an object of this invention to provide a method of forming a high aspect ratio metal plate pattern and a conductor pattern on a circuit board by multi-stage etching to obviate the conventional problems of the insufficient masking property in (1) and of the separation of the dry film resist (DFR) in the multi-stage etching process described in (1), (2) and (3) above.

In order to achieve the object described above, according to one aspect of the present invention, there is provided a method of forming a metal plate pattern, comprising the steps of coating a resist on one or two surfaces of a metal plate and forming a resist pattern by patterning the resist, forming by pattern plating a metal layer of a metal of a different type from the metal plate at a portion of the resist pattern not masked, removing the resist, half etching the metal plate with the metal plating layer as a first mask, coating a positive resist on the surface half etched on the first mask and by exposure and development from the upper portion of the first mask, forming a positive resist as a second mask on the side etched layer formed under the first mask, half etching the metal plate again through the first and second masks, and removing the first and second masks.

According to another aspect of the invention, there is provided a method of forming a circuit board, comprising the steps of coating a resist on a metal foil formed on one or two surfaces of an insulating base member and forming a resist pattern by patterning the resist, forming by pattern plating a metal layer of a metal of a different type from the metal foil at a portion of the resist pattern not masked, removing the resist, half etching the metal foil with the metal plating layer as a first mask, coating a positive resist on the half etched surface from the upper portion of the first mask and, by exposure and development from the upper portion of the first mask, forming a positive resist as a second mask on the side etching layer formed under the first mask, half etching the metal foil again through the first and second masks, and removing the first and second masks.

In this aspect of the invention, the step of coating, exposing and developing the positive resist and forming a positive resist on the side etched layer under the first mask and the step of half etching the metal plate or the metal foil again through the first and second masks are repeatedly conducted.

Also, the metal plate or the metal foil is formed of copper, iron or iron-nickel alloy soluble in the etching solution used, and the metal plating layer is a tin plating layer, a solder plating layer, a silver plating layer or a gold plating layer which is not dissolved by the etching solution.

Further, the resist coated on the metal plate or the metal foil is a dry film resist, and the positive resist is a liquid positive resist or an electrodeposit resist.

According to still another aspect of the invention, there is provided a method of forming a metal plate pattern, comprising the steps of dipping the metal plate pattern fabricated by the aforementioned forming method, and the metal of the same type as or a different type from the metal plate pattern, in an electrolytic solution, and applying a voltage between the metal plate pattern in the electrolytic solution as a positive electrode and the metal of the same or different type as a negative electrode and electrolytically polishing by preferential elution of the protrusions on the surface of the metal plate pattern.

According to a further aspect of the invention, there is provided a method of forming a circuit board, comprising the steps of dipping the circuit board fabricated by the aforementioned forming method and the metal of the same type as or a different type from the pattern metal of the circuit board in an electrolytic solution, and applying a voltage between the circuit board in the electrolytic solution as a positive electrode and the metal of the same or different type as a negative electrode and electrolytically polishing by preferential elution of the protrusions on the surface of the circuit board.

### BRIEF DESCRIPTION OF THE DRAWINGS

FIG. 1 shows the steps of a method of forming a metal plate pattern by multi-stage etching from one surface of a metal plate according to a first embodiment of the invention.

FIG. 2 shows the steps of a method of forming a metal plate pattern following the process shown in FIG. 1.

FIG. 3 shows the steps of a method of forming a metal plate pattern by multi-stage etching from the two surfaces of a metal plate according to a second embodiment of the invention.

FIG. 4 shows the steps of a method of forming a metal plate pattern following the process shown in FIG. 3.

FIG. 5 shows the steps of a method of forming a metal plate pattern following the process shown in FIG. 4

FIG. 6 shows the steps of a method of forming a circuit board by multi-stage etching from one surface of a resin substrate according to a third embodiment of the invention.

FIG. 7 shows the steps of a method of forming a circuit board following the process shown in FIG. 6.

FIG. 8 shows the steps of a method of forming a circuit board by multi-stage etching from the two surfaces of a resin substrate according to a fourth embodiment of the invention.

FIG. 9 shows the steps of a method of forming a circuit board following the process shown in FIG. 8.

FIG. 10 shows the steps of a method of forming a circuit board following the process shown in FIG. 9.

FIG. 11 shows a metal partitioning wall after a plurality of etching sessions and removing the resist.

FIG. 12 shows the process of electrolytically polishing the metal partitioning wall.

FIG. 13 shows the metal partitioning wall after electrolytic polishing.

### DESCRIPTION OF THE PREFERRED EMBODIMENTS

Embodiments of the invention are described in detail below with reference to the accompanying drawings.

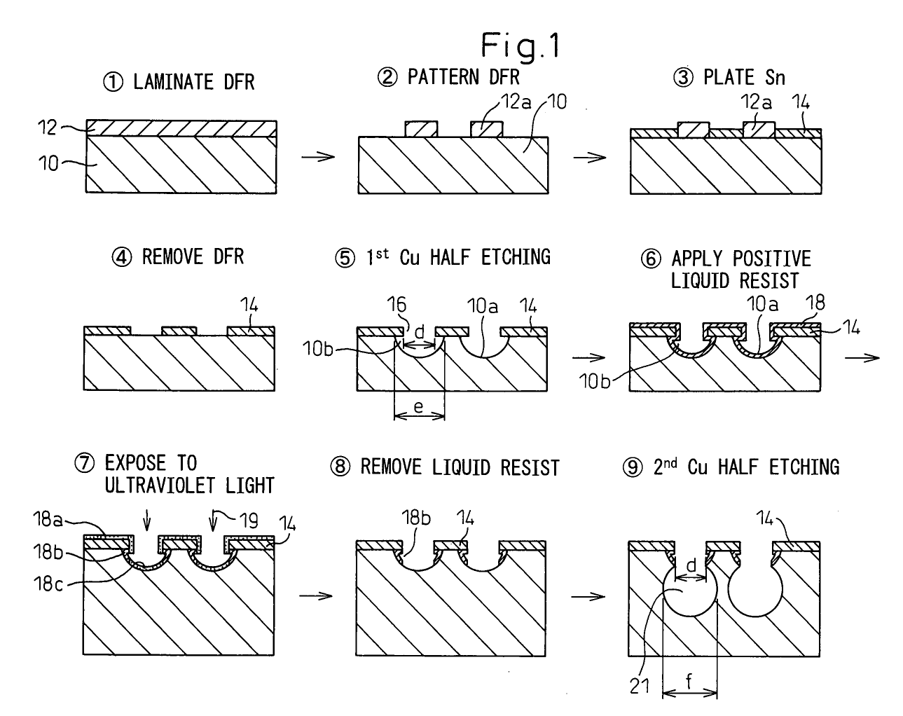

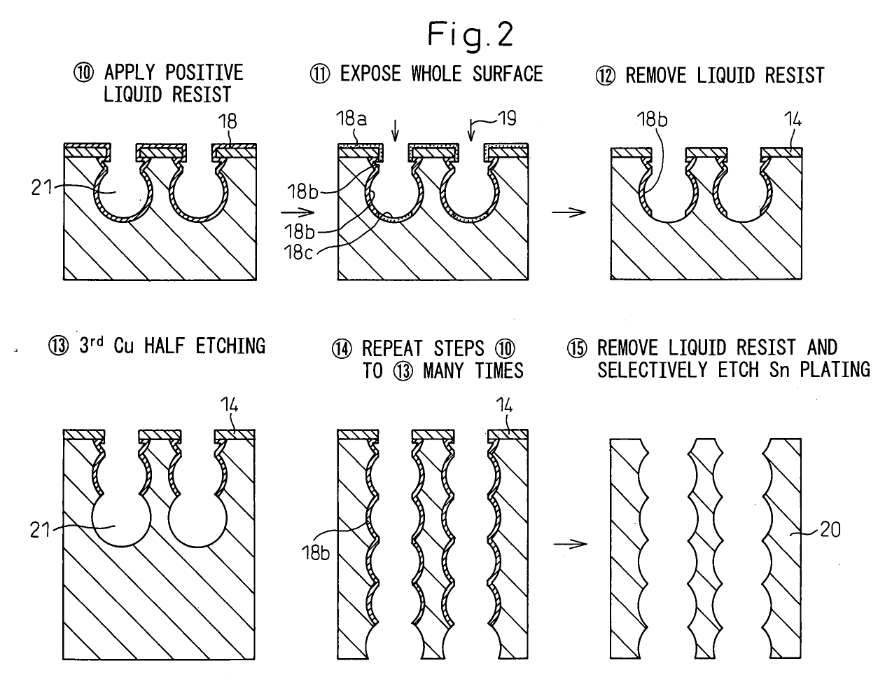

FIGS. 1 and 2 show the steps of a method of forming a metal plate pattern such as a lead frame using the semiadditive process according to a first embodiment of the invention. According to the first embodiment, the metal plate pattern is formed by conducting the multi-stage etching from one surface of a metal plate.

In a first step, one surface of a metal plate 10, made of copper as a basic metal member, is coated in its entirety with a laminate dry film resist (DFR) 12, which is patterned by being exposed and developed with a predetermined mask pattern (not shown) in a second step.

In a third step, with the patterned DFR 12a as a mask, a tin plating layer 14 is formed in the openings or grooves of the DFR 12a by electrolytic plating using the metal plate 10 as one of the electrodes. In a fourth step, the DFR 12a is separated, by a well-known method, to leave the tin plating pattern 14 on the metal plate 10.

In a fifth step, the half etching or selective etching is conducted by spraying an etching solution on the metal plate 10 with the tin plating pattern 14 as a mask. In this half etching process, each area of the metal plate 10 around the portion under the etching solution spraying region is removed by the etching solution with the tin plating pattern as a first mask. Each removed area of the metal plate 10 fails to reach the lower surface of the metal plate 10. On the other hand, the surface portion 10b under the masking is also etched by what is called the side etching. In the first half etching session, therefore, the conditions (etching time, etc.) are adjusted to remove the area of the metal plate 10 within a predetermined range.

As a result, as shown, in each upper portion of the metal plate 10 in proximity to the first mask pattern 14, the removed portion of the metal plate 10 somewhat intrudes into the metal plate 10 from the width (d) of each portion of the first mask pattern 14 where the etching solution passes. Thus, a side etched portion 10b is formed in which the width (e) of the removed portion is larger than the width (d) of the first mask pattern. On the other hand, each groove portion removed by etching of the metal plate 10 fails to reach the lower surface of the metal plate 10 and constitutes a substantially U-shaped groove 10a having a somewhat rounded cross section.

Next, in a sixth step, the whole surface including the portion half etched in the preceding step is coated with a positive liquid resist 18. In this case, the positive liquid resist 18 is applied on the upper and side surfaces of the tin plating pattern layer 14, the bottom portion of each substantially U-shaped groove 10a of the metal plate 10 removed by etching and each side etched portion 10b.

In a seventh step, parallel ultraviolet light rays 19 are radiated from the upper surface of the positive liquid resist 18 for exposure. The ultraviolet light 19 used for exposure is desirably parallel light radiated in the direction perpendicular to the surface of the mask on the metal plate 10. The ultraviolet light 19, however, is not necessarily parallel light if capable of reaching deep into the positive liquid resist 18.

In this exposure step, the light-exposed portions of the positive liquid resist 18 including each portion 18a of the positive liquid resist 18 on the tin plating pattern layer 14, the portion thereof on each side surface of the tin plating pattern layer 14 and each portion 18c on the bottom of the substantially U-shaped groove 10a. In other words, the area 18b on the side etched portion 10b under the tin plating pattern layer 14 removed somewhat inward of the metal plate 10 from the mask pattern width (d) in the preceding half etching step remains unexposed.

Instead of coating the liquid resist 18, the positive resist 18 may be formed by electrodeposition in which the resist is attached only to the portions having a metal surface.

Next, in an eighth step, the liquid resists 18a, 18c in the elutable portion are developed and removed, while leaving the settled resist 18b on the side etched portion 10b as it is. In this way, the side etched portion 10b of the metal plate 10 forming an etched layer is protected from the effect of the next etching session.

In a ninth step, the second half etching or selective etching is carried out by applying the etching solution to the metal plate 10 formed with a second mask constituted of the tin plating pattern layer 14 and the resist 18b protecting the surface of the side etched portion. In this second half etching step, the portion 10a of the metal plate not protected by the first and second masks is etched and a groove 21 having a substantially circular cross section is formed. The width (f) of this groove 21 is larger than the mask pattern width (d) of the tin plating layer 14.

Next, tenth and subsequent steps according to the first embodiment are explained with reference to FIG. 2. First, in the tenth step, the positive liquid resist 18 is coated again over the whole surface including the portion subjected to the second half etching in the preceding step.

In an 11th step, the parallel ultraviolet light 19 is radiated from the upper surface of the positive liquid resist 18 for exposure, followed by development. Like in the seventh step described above, the ultraviolet light used for exposure is desirably the parallel light radiated in the direction perpendicular to the surface of the masking on the metal plate 10. In the case, however, if the light rays can reach deep into the positive liquid resist 18, the ultraviolet light is not necessarily parallel light.

In this exposure step, the portions of the positive liquid resist 18 exposed to light, i.e. the portion 18a on the tin plating pattern layer 14 of the positive liquid resist 18, the side surface portion of the tin plating pattern layer 14 and the portion 18c on the bottom of the substantially U-shaped groove 21 are exposed. In other words, as in the first half etching session, the area 18b on the side etched portion 10b under the tin plating pattern layer 14 which somewhat intrudes inward of the metal plate 10 from the mask pattern width (d) remains unexposed.

In a 12th step, the positive liquid resists 18a and 18c that have been melted are removed, while leaving only the resist 18b hardened, after which a third half etching session is conducted in a 13th step.

Subsequently, the process of tenth to 13th steps is repeated as many times as required (14th step). In the last 15th step, the remaining positive liquid resist 18b is removed while at the same time etching off the tin plating layer 14.

Finally, therefore, a high aspect ratio lead or metal plate pattern 20 is produced in which the width difference is small between the upper and lower surfaces in the cross section of the lead 20 of the lead frame having a conductor pattern. As a result, the width of the lead of the lead frame can be minimized.

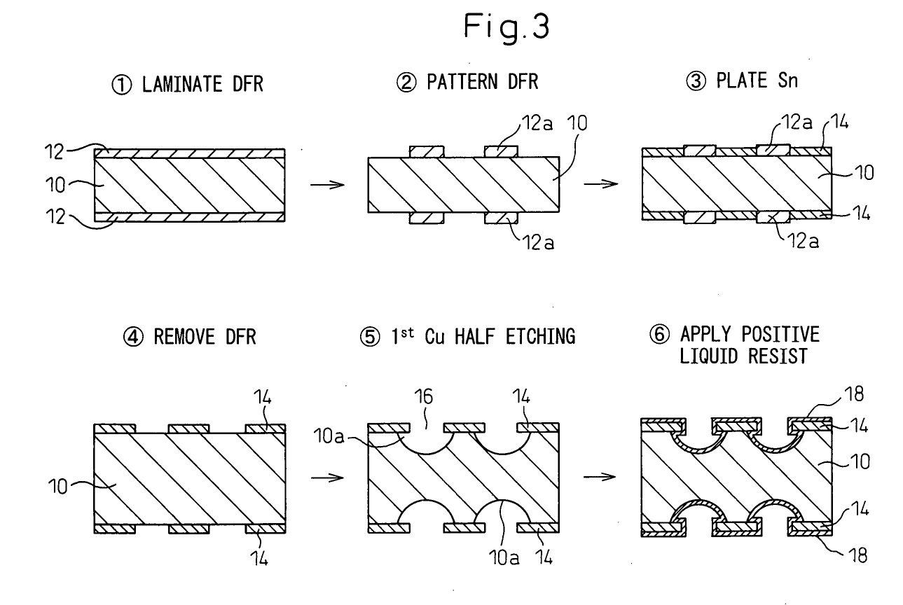

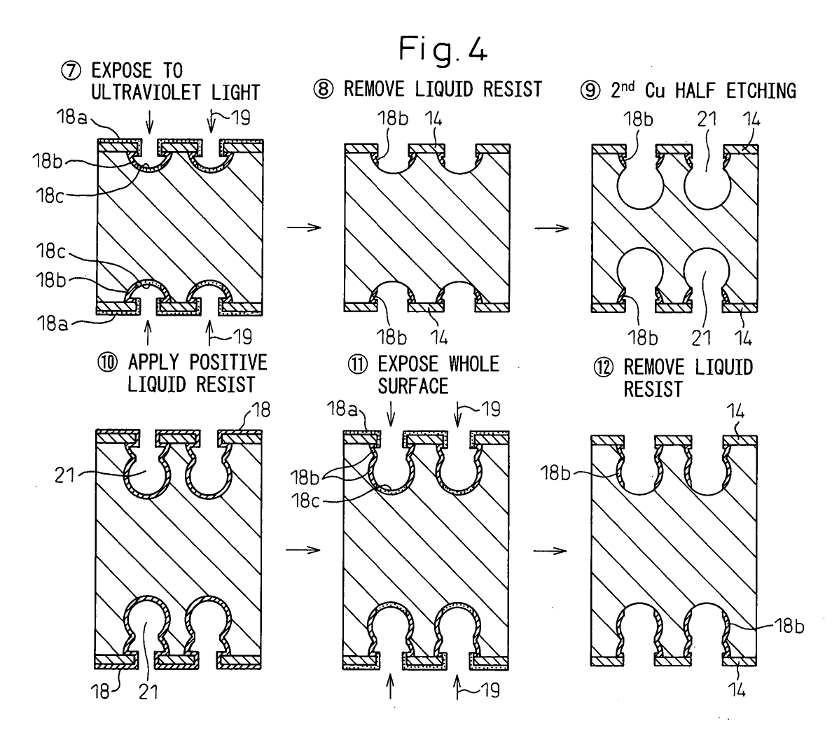

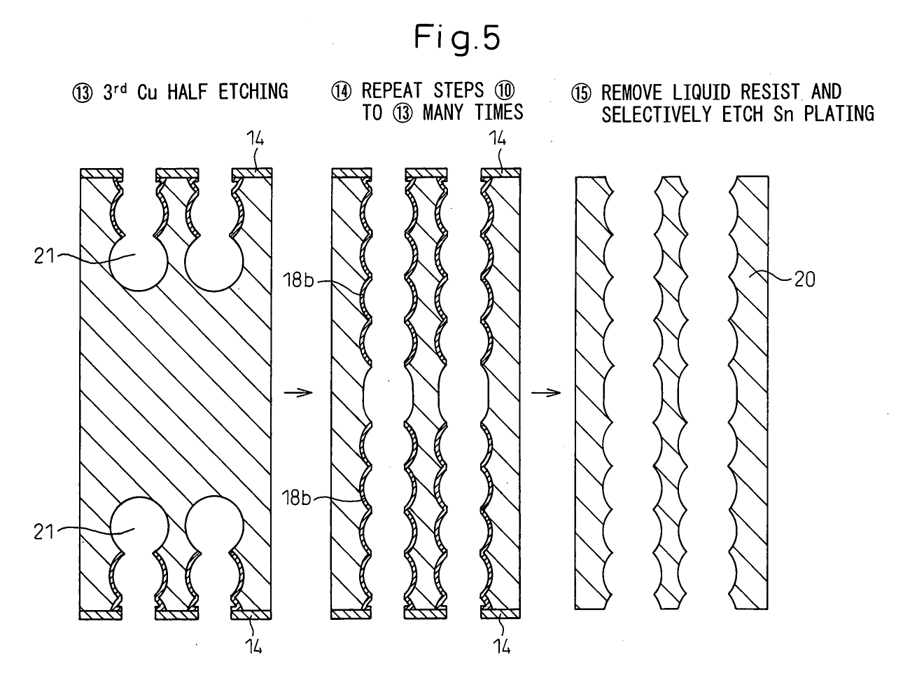

FIGS. 3 to 5 show the steps of a method of forming a metal plate pattern such as a lead frame or a metal mesh according to a second embodiment of the present invention using the semiadditive method. According to the second embodiment, the metal plate pattern is formed by multi-stage etching from the two surfaces of a metal plate.

Except that the two surfaces of the metal plate are processed at the same time, the second embodiment is basically similar to the first embodiment in which the processing is started from only one surface of the metal plate. Specifically, in a first step, a dry film resist (DFR) 12 in laminate form is coated over the whole of the upper and lower surfaces of the metal plate 10 of copper as a base metal member. In a second step, the resist is patterned by exposure and development in a predetermined mask pattern.

In third step, a tin plating layer 14 is formed on each opening of the DFR 16 using the patterned DFR 12a as a mask in a similar manner on the upper and lower surfaces of the metal plate 10. In a fourth step, the DFR 12a is separated by a well-known method while at the same time leaving the tin plating layer 14 on the metal plate 10. In a fifth step, an etching solution is applied to the two surfaces of the metal plate 10 at the same time with the tin plating pattern 14 as a first mask, so that each surface is half etched or selectively etched. As a result, a substantially U-shaped groove 10a having a generally rounded cross section is formed at each portion removed by etching on the two surfaces of the metal plate 10.

Next, in a sixth step, the positive liquid resist 18 is applied to the whole of the two surfaces of the metal plate 10 including the portions half etched in the preceding step. In a seventh step, the parallel ultraviolet light 19 is radiated for exposure from the upper surface of the positive liquid resist 18 on the two surfaces of the metal plate 10.

In an eighth step, the liquid resists 18a and 18c in the elutable portions are removed while leaving only the resist 18b on the hardened side etched portion 10b. In a ninth step, a second half etching or selective etching process is conducted by applying the etching solution using, as a second mask, the portion of the resist 18b protecting the surface of the side etched portion and the remaining tin plating pattern layer 14.

In a tenth step, the positive liquid resist 18 is applied again over the whole of the two surfaces of the metal plate 10. In an 11th step, the parallel ultraviolet light 19 is radiated for exposure on the positive liquid resist 18 from the two surfaces of the metal plate.

In a 12th step, the positive liquid resists 18a and 18c now in melted form are developed and removed, followed by a 13th step in which a third half etching session is conducted.

Subsequently, the tenth to 13th steps described above are repeated for the required number of times (14th step). In the last 15th step, the remaining positive liquid resist 18b is removed while at the same time selectively etching-off the tin plating layer 14.

As a result, a high aspect ratio lead or metal pattern 20 a can be finally obtained. Also, according to the second embodiment, the multi-stage etching is carried out from the two surfaces of the metal plate 10, and therefore a metal pattern still higher in aspect ratio can be formed. Further, the multi-stage etching carried out from the two surfaces of the metal plate can form a metal pattern within a shorter length of time.

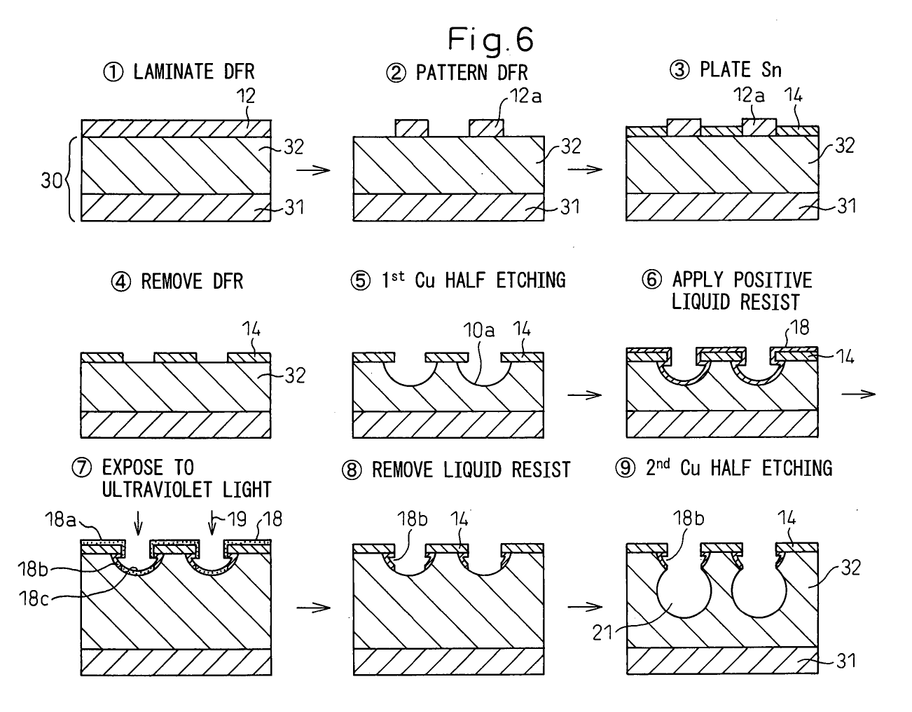

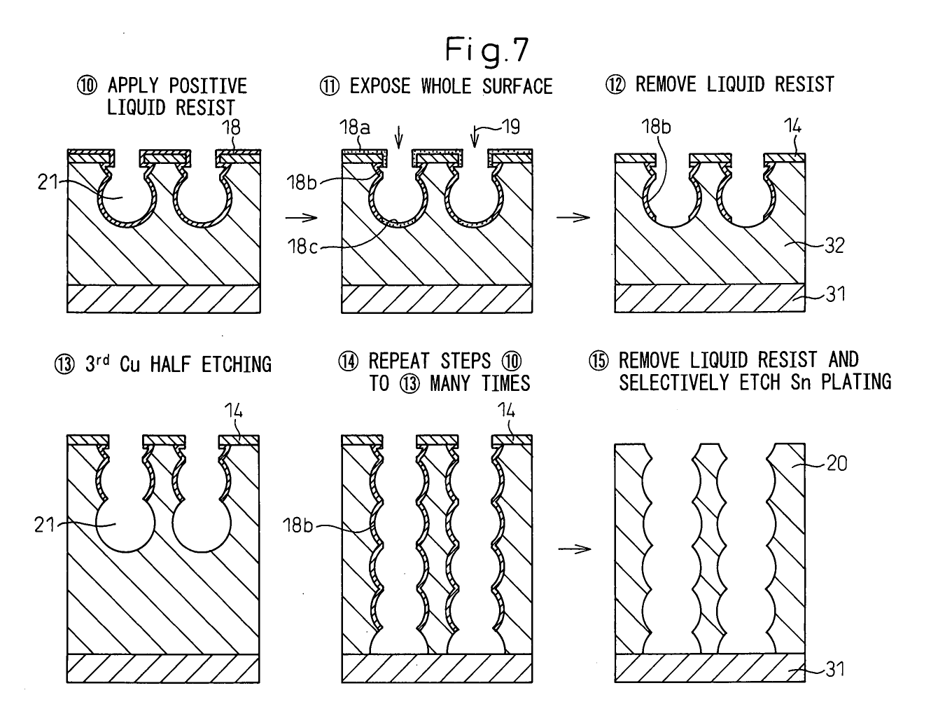

FIGS. 6 and 7 show the steps of a method of forming a wiring pattern on a circuit board according to a third embodiment of the present invention. In the third embodiment, the circuit board is formed by multi-stage etching, from one surface of the two-side copper-clad resin plate, in which the wiring pattern is formed similarly to the metal plate pattern in the first embodiment.

In a first step, the whole of one surface of the two-side copper-clad resin plate 30 carrying a copper foil 32 on both surfaces of an insulating base member 31 is coated with a laminate dry film resist (DFR) 12. In a second step, the resist is patterned by exposure and development with a predetermined mask pattern (not shown).

In a third step, with the patterned DFR 12a as a mask, a tin plating layer 14 is formed in each opening of the DFR 12a by electrolytic plating with the copper foil 32 as one electrode. In a fourth step, the DFR 12a is separated by a well-known method while leaving the tin plating pattern 14 on the copper foil 32.

In a fifth step, the etching solution is applied to the copper foil 32 with the tin plating pattern 14 as a first mask thereby to conduct half etching or selective etching. In the half etching process, the area around the copper foil 32 under the portion of the tin plating pattern 14 constituting the first mask where the etching solution passes is removed. The removed area of the copper foil 32 fails to reach the lower surface of the copper foil 32, while the surface portion of the lower part of the mask is also etched in what is called “side etching”. Thus, the conditions for half etching (etching time, etc.) are adjusted so that the removed area of the copper foil 32 covers not more than a predetermined range.

As a result, as shown, the side etched portion 10b is formed at the upper portion of the copper foil 32 in proximity to the first mask pattern 14, while each removed groove portion constitutes a substantially U-shaped groove 10a having a generally rounded cross section.

In a sixth step, the positive liquid resist 18 is coated over the entire surface including the portion half etched in the preceding step. In this case, the positive liquid resist 18 is coated on the upper and side surfaces of the tin plating pattern layer 14, the bottom portion of the substantially U-shaped groove 10a of the copper foil 32 removed by etching and the side etched portion 10b.

Next, in a seventh step, the parallel ultraviolet light 19 is radiated from the upper surface of the positive liquid resist 18 for exposure.

In an eighth step, the elutable liquid resists 18a and 18c are removed by development, and only the resist 18b on the hardened side etched portion 10a is left as it is. In a ninth step, the etching solution is applied to carry out the second half etching or selective etching using, as a second mask, the portion of the resist 18b protecting the surface of the remaining tin plating pattern layer 14 and the side etched portion. In a tenth step, the positive liquid resist 18 is applied again over the whole surface including the portion subjected to the second half etching session in the preceding step. In an 11th step, the parallel ultraviolet light 19 is radiated from the upper surface of the positive liquid resist 18 for exposure.

Next, in a 12th step, the positive liquid resists 18a and 18b adapted for elution are removed by development, followed by a 13th step to conduct a third half etching session.

After that, the process of the tenth to 13th steps is repeated as many times as required (14th step). In the last 15th step, the positive liquid resist 18b is removed while, at the same time, selectively etching off the tin plating layer 14.

Finally, therefore, a circuit board having a high aspect ratio wiring pattern 20 is formed.

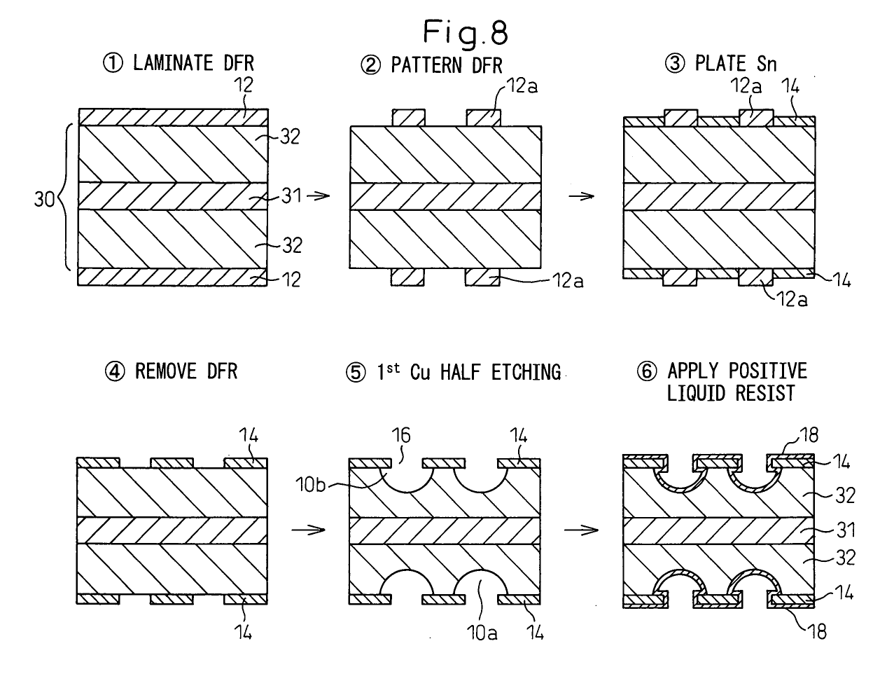

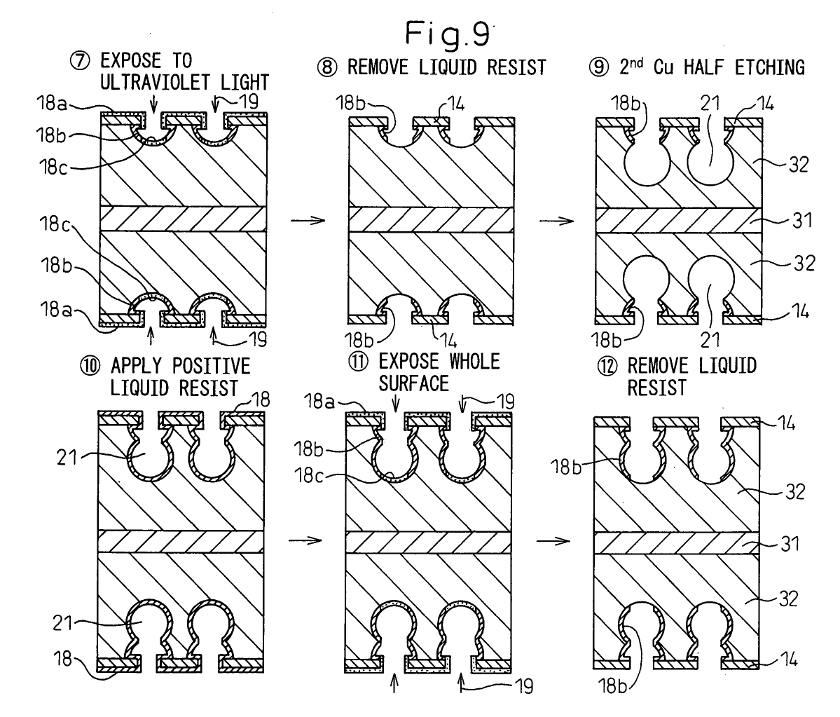

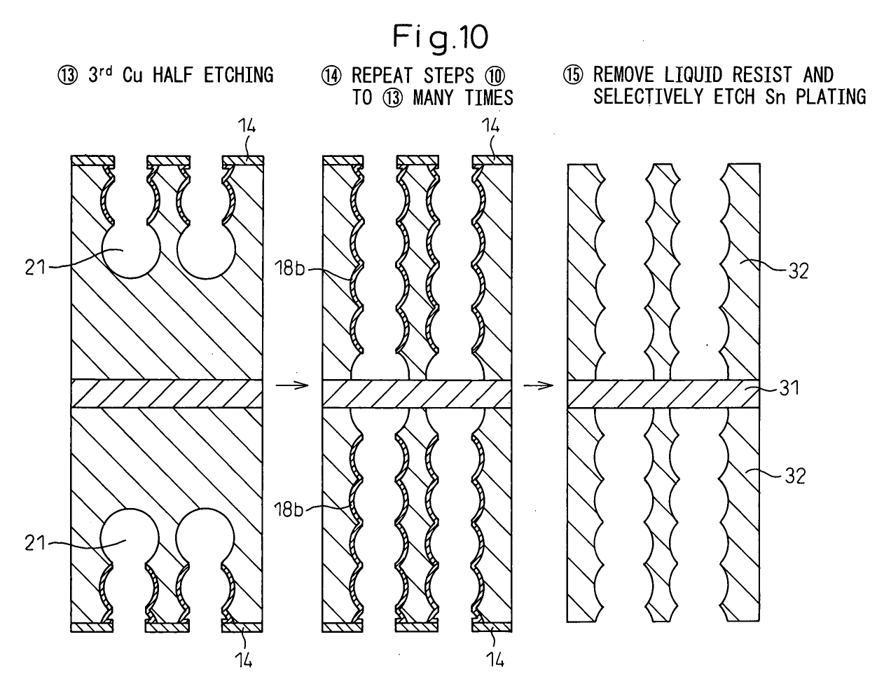

FIGS. 8 to 10 show a method, step by step, of forming a conductor pattern on a circuit board according to a fourth embodiment of the present invention.

According to the fourth embodiment, the circuit board is formed by multi-stage etching from the two surfaces of a two-sided copper-clad resin plate. This embodiment is similar to the third embodiment for forming a circuit board and also similar to the second embodiment in starting the processing from the two surfaces at the same time. Therefore, this embodiment is not described in detail.

According to the fourth embodiment, a circuit board having a high aspect ratio wiring pattern can be finally formed. The fourth embodiment is explained above with reference to a case having the same wiring pattern on the upper and lower surfaces of the resin substrate 31. Nevertheless, different wiring patterns may be formed concurrently on the upper and lower surfaces of the resin substrate 31 depending on the type of the circuit board.

In forming a lead frame or a wiring pattern on the insulating substrate according to each of the first to fourth embodiments described above, the type of the etching solution, the etching time and other parameters must, of course, be adjusted appropriately in accordance with various conditions including the material, thickness, pitches and the inter-pattern distance of the metal patterns.

Also, in spite of the foregoing description of a case in which the metal plate is formed of copper (first and second embodiments) or copper is attached on the resin substrate (third and fourth embodiments) as a base member to be etched, the metal base member can alternatively be formed of iron, iron-nickel alloy, etc. as well as copper.

The foregoing explanation refers to a case in which the mask layer used for selectively etching the metal substrate is formed of the tin plating as a metal not dissolved in the etching solution for melting the copper of the base member. Nevertheless, a metal other than tin such as solder plating, silver plating or gold plating, which is not dissolved, can be used as a mask in the process of removing the metal (copper, iron or iron-nickel alloy) constituting the base member by etching. These metals can be appropriately selected from the viewpoint of type and cost of the base metal member.

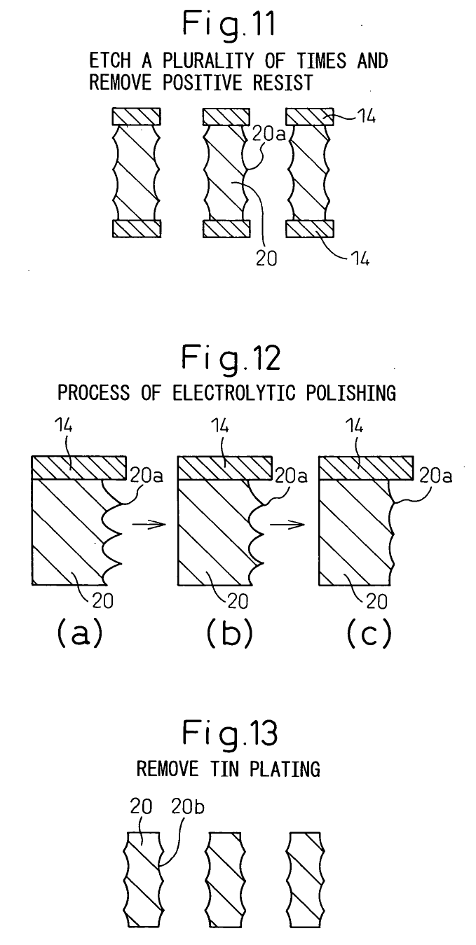

FIGS. 11 to 13 show a method of flattening by eliminating the protrusions remaining on the metal plate pattern or the high aspect ratio wiring pattern formed as the result of conducting a plurality of etching sessions according to the first to fourth embodiments. With the partitioning wall of the metal pattern as a positive electrode and the metal of the same type as the metal partitioning wall as an opposite electrode, the two electrodes are immersed in an electrolytic solution. Upon application of a voltage between the two electrodes, the electric field is concentrated on the protrusions of the metal partitioning wall constituting the positive electrode, from which elution occurs first, thereby making it possible to flatten the partitioning wall surface of the metal pattern. The process of this electrolytic polishing is explained below.

FIG. 11 shows a state in which the tin plating pattern 14 still remains after removing the positive resist protecting the side etching layer by a plurality of etching sessions. Protrusions 20a remain on the partitioning wall surface of the metal pattern 20 after the plurality of etching sessions.

In a partly enlarged view of FIG. 12 showing the partitioning wall surface of the metal pattern 20, the positive electrode constituted of the partitioning wall of the metal pattern 20 and the negative electrode constituted of a metal (such as copper) of the same type as the metal partitioning wall (such as copper) are immersed in the electrolytic solution, and a voltage is applied between the two electrodes to cause the elution of the positive electrode. The electric field is concentrated on the protrusions 20a of the metal partitioning wall, and therefore the protrusions 20a on the surface of the partitioning wall are eluted into the electrolytic solution preferentially. As shown in FIGS. 12 (a) to 12(c), therefore, the flatness degree of the metal partitioning wall gradually increases during the electrolytic polishing process. Once the tin plating layer 14 is removed finally, therefore, as shown in FIG. 13, the metal pattern 20 having a partitioning wall 20b high in flatness degree is formed.

In the electrolytic polishing process shown in FIGS. 11 to 13, a metal used as an electrode opposed to the metal plate pattern or the wiring pattern constituting a positive electrode is of the same type of metal as the metal plate pattern or the wiring pattern, as the case may be. As an alternative, a different type of metal may be used as a negative electrode. Then, the two electrodes may be dipped in an electrolytic solution and a voltage applied between them to conduct the electrolytic polishing process. Also, in such a case, the electric field is concentrated at the protrusions of the partitioning wall of the metal plate pattern or the wiring pattern, and the protrusions are eluted into the electrolytic solution preferentially, so that the metal partitioning wall is further flattened.

The embodiments of the invention are explained above with reference to the accompanying drawings. This invention is not limited to those embodiments, and can be variously modified or altered without departing from the scope and spirit of the invention.

As described above, according to this invention, the pitch of the metal plate pattern or the wiring pattern of the circuit board can be made narrow. Also, the width of the upper portion of the metal plate pattern or the wiring patter can be secured, so that the difference in pattern width between the upper portion and the lower portion can be reduced thereby to increase the aspect ratio.

In view of the fact that a metal mask having an appropriate thickness is used as a mask layer of the positive resist, the problems in the prior art using the DFR in which the positive resist under the DFR is melted and a gap is formed with the DFR at the time of forming an anti-etching protective film of the side etched portion due to the insufficient masking ability, resulting in the loss of a function as an anti-etching protective layer, the DFR is dissolved (expanded) and separated by the developer at the time of development of the positive resist, or the DFR is deformed under the pressure of the developer resulting in a lower adhesion of the DFR and separation leading to the loss of the masking function, are eliminated.

1. A method of forming a metal plate pattern, comprising the steps of:
coating a resist on one or two surfaces of a metal plate and forming a resist pattern by patterning the resist;
forming by pattern plating a metal layer of a metal of a different type from the metal plate at a portion of the resist pattern not masked;
removing the resist;
half etching the metal plate with the metal plating layer as a first mask;
coating a positive resist on the half etched surface from the upper portion of the first mask and by exposure and development from the upper portion of the first mask, forming a positive resist as a second mask on the side etched layer formed under the first mask;
half etching the metal plate again through the first and second masks; and
removing the first and second masks.

2. The method of forming a metal plate pattern according to claim 1,
wherein the step of coating, exposing and developing the positive resist, the step of forming a positive resist on the side etched layer under the first mask and the step of half etching the metal plate again through the first and second masks are repeatedly executed.

3. The method of forming a metal plate pattern according to claim 1,
wherein the metal plate is formed of a selected one of copper, iron and iron-nickel alloy soluble by the etching solution used, and the metal plating layer is formed of a selected one of tin, solder, silver and gold not soluble in the etching solution.

4. The method of forming a metal plate pattern according to claim 1,
wherein the resist coated on the metal plate is a dry film resist, and the positive resist is a liquid positive resist or an electrodeposited positive resist.

5. A method of forming a circuit board, comprising the steps of:
coating a resist on one or two surfaces of an insulating base member and forming a resist pattern by patterning;
forming by pattern plating a metal layer of a metal of a different type from the metal foil at a portion of the resist pattern not masked;
removing the resist;
half etching the metal foil with the metal plating layer as a first mask;
coating a positive resist on the half etched surface from the upper portion of the first mask and by exposure and development from the upper portion of the first mask, forming a positive resist as a second mask on the side etching layer formed under the first mask;
half etching the metal foil again through the first and second masks; and
removing the first and second masks.

6. The method of forming a circuit board according to claim 5,
wherein the step of coating, exposing and developing the positive resist and protecting a positive resist under the first mask and the step of half etching the metal foil again through the first and second masks are repeatedly carried out.

7. The method of forming a circuit board according to claim 5,
wherein the metal foil is formed of a selected one of copper, iron and iron-nickel alloy soluble in the etching solution used, and the metal plating layer is formed of a selected one of tin, solder, silver and gold not soluble in the etching solution.

8. The method of forming a circuit board according of claim 5,
wherein the resist coated on the metal foil is a dry film resist, and the positive resist is a selected one of a liquid positive resist and an electrodeposited positive resist.

9. A method of forming a metal plate pattern, comprising the steps of:
coating a resist on one or two surfaces of a metal plate and forming a resist pattern by patterning the resist;
forming by pattern plating a metal layer of a metal of a different type from the metal plate at a portion of the resist pattern not masked;
removing the resist;
half etching the metal plate with the metal plating layer as a first mask;
coating a positive resist on the half etched surface from the upper portion of the first mask and by exposure and development from the upper portion of the first mask, forming a positive resist as a second mask on the side etching layer formed under the first mask;
half etching the metal plate again through the first and second masks;
removing the first and second masks;
dipping the metal plate and a metal of different type from the metal plate in an electrolytic solution; and
applying a voltage between the metal plate pattern in the electrolytic solution as a positive electrode and the metal of different type from the metal plate as a negative electrode and electrolytically polishing by preferentially eluting the protrusions on the surface of the metal plate pattern.

10. A method of forming a metal plate pattern, comprising the steps of:
coating a resist on one or two surfaces of a metal plate and forming a resist pattern by patterning the resist;
forming by pattern plating a metal layer of a metal of a different type from the metal plate at a portion of the resist pattern not masked;
removing the resist;
half etching the metal plate with the metal plating layer as a first mask;
coating a positive resist on the half etched surface from the upper portion of the first mask and by exposure and development from the upper portion of the first mask, forming a positive resist as a second mask on the side etching layer formed under the first mask;
half etching the metal plate again through the first and second masks;
removing the first and second masks;
dipping the metal plate and a metal of the same type as the metal plate in an electrolytic solution; and
applying a voltage between the metal plate pattern in the electrolytic solution as a positive electrode and a metal of the same type as the metal plate as a negative electrode and electrolytically polishing by preferentially eluting the protrusions on the surface of the metal plate pattern.

11. A method of forming a circuit board device, comprising the steps of:
coating a resist on one or two surfaces of an insulating base member and forming a resist pattern by patterning;
forming by pattern plating a metal layer of a metal of a different type from the metal foil at a portion of the resist pattern not masked;
removing the resist;
half etching the metal foil with the metal plating layer as a first mask;
coating a positive resist on the half etched surface from the upper portion of the first mask and by exposure and development from the upper portion of the first mask, forming a positive resist as a second mask on the side etching layer formed under the first mask;
half etching the metal foil again through the first and second masks, and removing the first and second masks;
removing the first and second masks to form a circuit board;
dipping the circuit board and a metal in an electrolytic solution; and
applying a voltage between the circuit board in the electrolytic solution as a positive electrode and the metal as a negative electrode and electrolytically polishing by preferentially eluting the protrusions on the surface of the circuit board.

12. A method of forming a circuit board device, comprising the steps of:
coating a resist on one or two surfaces of an insulating base member and forming a resist pattern by patterning;
forming by pattern plating a metal layer of a metal of a different type from the metal foil at a portion of the resist pattern not masked;
removing the resist;
half etching the metal foil with the metal plating layer as a first mask;
coating a positive resist on the half etched surface from the upper portion of the first mask and by exposure and development from the upper portion of the first mask, forming a positive resist as a second mask on the side etching layer formed under the first mask;
half etching the metal foil again through the first and second masks, and removing the first and second masks;
removing the first and second masks to form a circuit board;
dipping the and a metal of the same type as the metal foil forming the circuit board in an electrolytic solution; and
applying a voltage between the circuit board in the electrolytic solution as a positive electrode and the metal of the same type as the metal foil as a negative electrode and electrolytically polishing, by preferentially elution, the protrusions on the surface of the circuit board.
